(19) United States
(12) Patent Application Publication
(10) Pub. No.: US 2014/0158988 A1
(43) Pub. Date: Jun. 12, 2014

(54) GRAPHENE TRANSISTOR

(71) Applicant: National Taiwan University, Taipei City (TW)

(72) Inventors: Chun-wei Chen, Taipei City (TW); Po-hsun Ho, Taipei City (TW)

(21) Appl. No.: 13/910,963

(22) Filed: Jun. 5, 2013

(30) Foreign Application Priority Data
Dec. 7, 2012 (TW) 101146094

(51) Int. Cl. H01L 29/16

(52) U.S. Cl. CPC H01L 29/1606
USPC 257/29

(57) ABSTRACT

Disclosed is a graphene transistor. The graphene transistor includes a source electrode, a drain electrode, a graphene layer, an insulating layer, a gate electrode and at least one doping layer. The graphene layer is disposed between the source electrode and the drain electrode. The gate electrode is separated from the graphene layer, the source electrode and the drain electrode by the insulating layer. The doping layer is disposed on the graphene layer or beneath the graphene layer for providing dopants for the graphene layer. The doping layer includes nonstoichiometric compounds. The graphene transistor of the present invention has a superior air stability and is not easily affected by environment.

### CROSS REFERENCE TO RELATED APPLICATIONS

This application claims the priority of Taiwan Patent Application No. 101146094, filed on Dec. 7, 2012. This invention is partly disclosed in an article entitled “Self-Encapsulated Doping of n-Type Graphene Transistor with Extended Air Stability” on Jun. 8, 2012 completed by Po-Hsun Ho et al.

### FIELD OF THE INVENTION

The present invention generally relates to a transistor, and more particularly to a graphene transistor.

### BACKGROUND

Graphene has a high carrier mobility, and thus it is suitable for serving as an active element, such as a graphene transistor.

The graphene transistor may be manufactured as an N-type graphene transistor or a P-type graphene transistor. A method for manufacturing the N-type graphene transistor or the P-type graphene transistor is to implement N-type doping or P-type doping on the graphene transistor. However, the graphene transistor which is manufactured by implementing the N-type doping or the P-type doping has a poor stability, and thus applications of the graphene transistor are limited.

Furthermore, the graphene transistor made by a conventional doping method is easily affected by environment, and thus characteristics thereof are worsened. For instance, the N-type graphene transistor is easily affected by air and/or vapor in the environment, such that a doping level and the carrier mobility of the N-type graphene transistor are reduced and element characteristics are worsened.

Consequently, there is a need to solve the above-mentioned problems that the graphene transistor has the poor stability and the graphene transistor exposed in the air is easily affected by the environment.

### SUMMARY OF THE INVENTION

An object of the present invention is to provide a graphene transistor, which has a superior stability and is not easily affected by environment.

To achieve the above-mentioned object, an aspect of the present invention is to provide a graphene transistor, which comprises a source electrode, a drain electrode, a graphene layer, an insulating layer, a gate electrode and at least one doping layer. The graphene layer is disposed between the source electrode and the drain electrode. The gate electrode is separated from the graphene layer, the source electrode and the drain electrode by the insulating layer. The at least one doping layer is disposed on the graphene layer or beneath the graphene layer for providing dopants for the graphene layer. The doping layer comprises nonstoichiometric compounds.

To achieve the above-mentioned object, another aspect of the present invention is to provide a graphene transistor, which comprises a source electrode, a drain electrode, a graphene layer, an insulating layer, a gate electrode and a doping layer. The graphene layer is disposed between the source electrode and the drain electrode. The gate electrode is separated from the graphene layer, the source electrode and the drain electrode by the insulating layer. The doping layer is disposed on the graphene layer for sealing the graphene layer. The doping layer comprises nonstoichiometric compounds.

In the graphene transistor of the present invention, the graphene layer is highly doped by the doping layer which comprises the nonstoichiometric compounds. Moreover, disposing the doping layer on the graphene layer for sealing the graphene layer is capable of preventing the graphene layer from being affected by the air and vapor in the environment and avoiding that the doping level is reduced.

### BRIEF DESCRIPTION OF THE DRAWINGS

FIG. 1 illustrates a graphene transistor in accordance with a first embodiment of the present invention;

FIG. 2 illustrates a graphene transistor in accordance with a second embodiment of the present invention;

FIG. 3 illustrates a graphene transistor in accordance with a third embodiment of the present invention;

FIG. 4 illustrates that a graphene layer is sandwiched by two doping layers in FIG. 3;

FIG. 5 illustrates a graphene transistor in accordance with a fourth embodiment of the present invention;

FIG. 6A illustrates XPS spectra of C1s peaks when various concentrations of TiOx are utilized as the doping layer;

FIG. 6B illustrates Raman spectroscopy measurement when various concentrations of the TiOx are utilized as the doping layer;

FIG. 7 illustrates gate-dependent conductivity when various concentrations of the TiOx are utilized as the doping layer;

FIG. 8 illustrates gate-dependent conductivity curves when the graphene transistor in FIG. 3 is exposed in the air;

FIG. 9A illustrates a contact angle of the doping layer disposed on the insulating layer in the graphene transistor of the present invention; and

FIG. 9B illustrates a contact angle of the insulating layer in the conventional graphene transistor.

### DETAILED DESCRIPTION OF THE INVENTION

The technical scheme of the present invention will be further described in detail as follow by giving embodiments with reference to the accompanying drawings.

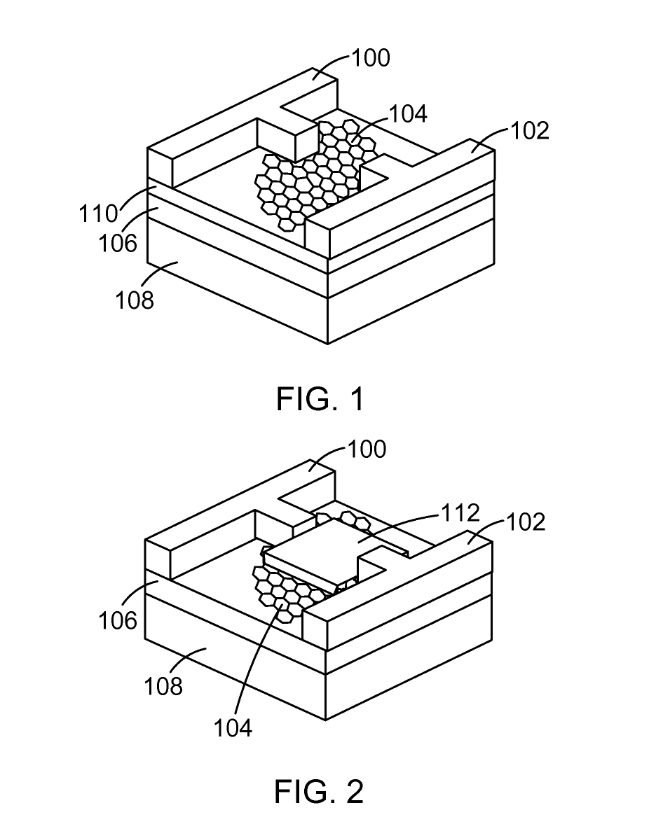

Please refer to FIG. 1, which illustrates a graphene transistor in accordance with a first embodiment of the present invention.

The graphene transistor of the present invention comprises a source electrode 100, a drain electrode 102, a graphene layer 104, an insulating layer 106, a gate electrode 108 and a doping layer 110.

In the present embodiment, the gate electrode 108 is a highly N-type doped silicon substrate. In another embodiment, the gate electrode 108 may be a highly P-type doped silicon substrate.

The insulating layer 106 is formed on the gate electrode 108. The insulating layer 106 may be silicon dioxide (SiO₂) or a suitable material. The gate electrode 108 is separated from the graphene layer 104, the source electrode 100 and the drain electrode 102 by the insulating layer 106.

Compared with the conventional graphene transistor, the graphene transistor of the present invention characterizes in that the doping layer 110 comprises nonstoichiometric compounds. The doping layer 110 may be disposed on the graphene layer 104 or beneath the graphene layer 104. In the present embodiment, the doping layer 110 is disposed beneath the graphene layer 104.

The graphene layer 104 is formed on the doping layer 110. The source electrode 100 and the drain electrode 102 are respectively disposed at two sides of the graphene layer 104. That is, the graphene layer 104 is disposed between the source electrode 100 and the drain electrode 102 and electrically coupled to the source electrode 100 and the drain electrode 102. The graphene layer 104 functions to be a channel layer of the graphene transistor. In the present embodiment, the doping layer including the nonstoichiometric compounds may provide N-type dopants for the graphene layer 104, such that the graphene layer 104 is N-type doped. Preferably, the nonstoichiometric compounds comprise titanium oxide (TiOx). The doping layer by utilizing the TiOx in accordance with the present invention has a doping level higher than that by utilizing organic molecules in the prior art.

Please refer to FIG. 2, which illustrates a graphene transistor in accordance with a second embodiment of the present invention.

In the first embodiment, the doping layer 110 which is utilized for providing the dopants is disposed beneath the graphene layer 104. In the present embodiment, the doping layer 112 is disposed on the graphene layer 104. The doping layer 112 including the nonstoichiometric compounds not only dopes the graphene layer 104 but also covers the graphene layer 104. In another embodiment, the doping layer 112 is capable of coving the whole graphene layer 104 for sealing the graphene layer 104, thereby preventing the graphene layer 104 from contacting with air. As a result, the graphene transistor of the present invention is not deteriorated because the graphene transistor is not affected by the air and vapor in the environment. That is, the graphene transistor has a superior air stability, because a surface of the graphene layer 104 does not contact with the air and/or vapor and the doping level is not reduced.

The source electrode 100, the drain electrode 102, the graphene layer 104, the insulating layer 106 and the gate electrode 108 are the same as those in the first embodiment and not repeated herein.

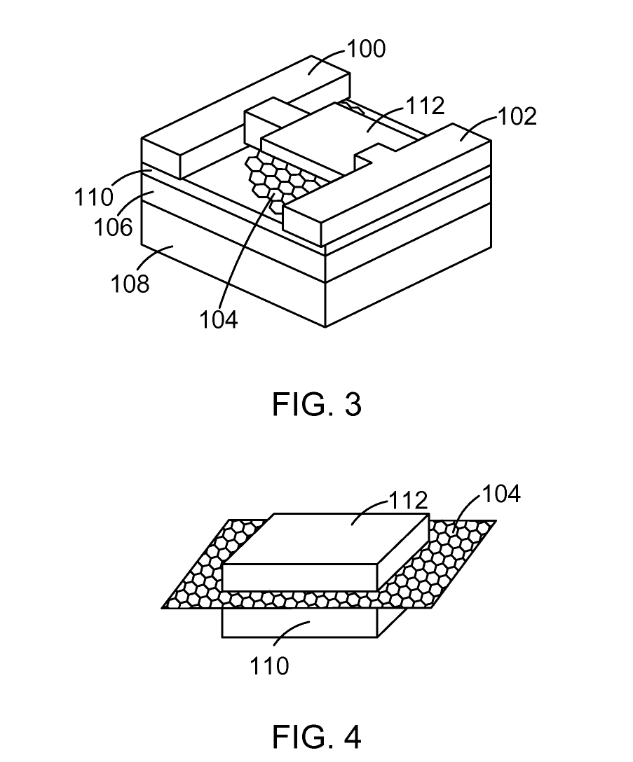

Please refer to FIG. 3 and FIG. 4. FIG. 3 illustrates a graphene transistor in accordance with a third embodiment of the present invention. FIG. 4 illustrates that the graphene layer 104 is sandwiched by two doping layers 110 and 112 in FIG. 3.

Different from the graphene transistors in the prior two embodiments, the graphene transistor in the third embodiment comprises the doping layer 112 and the doping layer 110 respectively disposed on the graphene layer 104 and beneath the graphene layer 104. The doping layer 110 beneath the graphene layer 104 is capable of providing the dopants for the graphene layer 104. The doping layer 112 on the graphene layer 104 is also capable of providing the dopants for the graphene layer 104 and covering the graphene layer 104, such that the graphene transistor has a superior air stability. In the present embodiment, the doping layers 112 and 110 may cover the whole graphene layer 104 to achieve the function of sealing the graphene layer 104, such that the graphene transistor has superior air stability. In addition, the doping level in FIG. 3 is higher than that of the graphene transistor which is only doped with a single doping layer on the top or at the bottom surface in FIG. 1 or FIG. 2.

Furthermore, since the doping layers 110 and 112 have hydrophobic characteristics, the graphene transistor has a superior vapor barrier property than that of the graphene transistor in FIG. 2.

The source electrode 100, the drain electrode 102, the graphene layer 104, the insulating layer 106 and the gate electrode 108 are the same as those in the first and second embodiments and not repeated herein.

The above-mentioned graphene transistors in the first, second and third embodiments are bottom-gate transistors, that is, the gate electrode 108 is disposed beneath the source electrode 100 and the drain electrode 102.

Preferably, the above-mentioned doping layers 110 and 112 respectively have a thickness of from about 10 nanometers (nm) to about 50 nm.

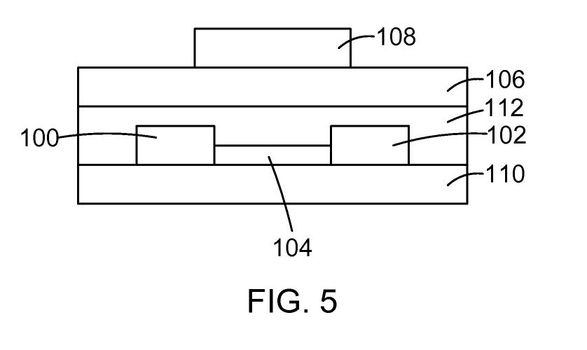

Please refer to FIG. 5, which illustrates a graphene transistor in accordance with a fourth embodiment of the present invention.

The graphene transistor of the present embodiment comprises a source electrode 100, a drain electrode 102, a graphene layer 104, an insulating layer 106, a gate electrode 108 and two doping layers 110 and 112. A difference among the present embodiment and the above-mentioned embodiments is that the graphene transistor in the present embodiment is a top-gate transistor, that is, the gate electrode 108 is disposed on the source electrode 100 and the drain electrode 102.

The graphene layer 104 is disposed between the source electrode 100 and the drain electrode 102 for serving as a channel layer of the graphene transistor. The graphene layer 104 is electrically coupled to the source electrode 100 and the drain electrode 102.

The doping layers 112 and 110 are respectively disposed on the graphene layer 104 and beneath the graphene layer 104. In the present embodiment, the doping layers 112 and 110 including the nonstoichiometric compounds provide the N-type dopants for the graphene layer 104, such that the graphene layer 104 is N-type doped. The doping layers 112 and 110 comprise the nonstoichiometric compounds. Preferably, the nonstoichiometric compounds comprise TiOx. The doping layer 112 on the graphene layer 104 not only provides the N-type dopants for the graphene layer 104 but also covers and seals the graphene layer 104, such that the graphene transistor has a superior air stability. Since the graphene transistor of the present embodiment comprises the two doping layers 110 and 112, the graphene layer 104 may be highly doped.

It is noted that the doping layer 112 in the graphene transistor of the present embodiment can cover the whole graphene layer 104 for achieving the function of sealing the graphene layer 104. In another embodiment, the doping layer 112 can only cover a part of the graphene layer 104.

The same as the first embodiment and the second embodiment, the graphene transistor of the present embodiment may comprise only one of the doping layers 110 and 112.

The gate electrode 108 is separated from the graphene layer 104, the source electrode 100 and the drain electrode 102 by the insulating layer 106. The insulating layer 106 may be silicon dioxide (SiO₂) or a suitable material.

In summary, the doping layers 110 and 112 of the present invention comprise the nonstoichiometric compounds which are capable of providing the N-type dopants. Moreover, the doping layers 110 and 112 by utilizing TiOx have a doping level higher than that by utilizing organic molecules in the prior art.

In the above-mentioned first embodiment to the fourth embodiment, the doping layers 110 and 112 may be formed by a solution process. The doping layers 110 and 112 are not required to be formed by a high temperature and toxic process. For instance, a titanium oxide (TiOx) film is deposited with a spin-coating method for forming the doping layers 110 and 112. It is noted that other suitable methods for forming the doping layers 110 and 112 are known for one skilled in the art of the present invention and not repeated herein.

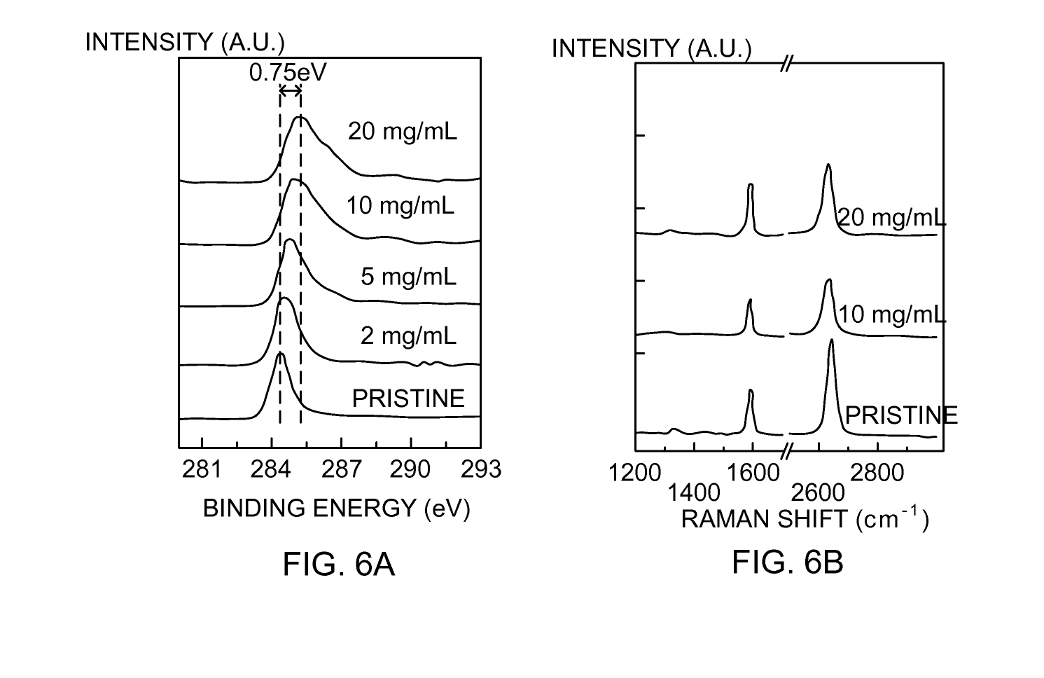

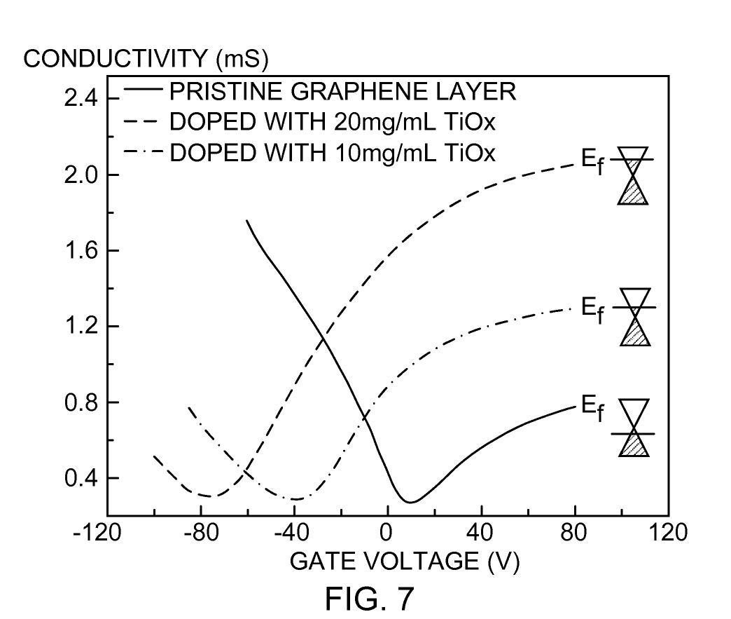

FIG. 6A, FIG. 6B and FIG. 7 describe that the graphene layer is doped by the doping layer which utilizes the TiOx in the present invention.

Please refer to FIG. 6A, which illustrates XPS (X-ray photoelectron spectroscopy) spectra of C1s peaks when various concentrations of the TiOx are utilized as the doping layer. The binding energy of the C1s peak of the pristine graphene (i.e. without the doping layer) corresponding to pure sp²-hybridized states is centered at 284.5±0.05 eV (electron volt). A gradual shift of the C1s peaks toward higher binding energies with the increased concentrations of the TiOx can be observed in FIG. 6A. The C1s peak is shifted by approximately 0.75 eV at the concentration of 20 mg/mL of the TiOx. Further increase in the concentrations of the TiOx does not cause a further shift of the C1s peaks but broadens their bandwidths. The shift of the binding energies is resulted from electron transfer at an interface between the TiOx (i.e. the doping layer) and the graphene layer, which moves the Fermi level toward or even higher than the Dirac point of graphene layer. That is, the doping layer provides the N-type dopants, such that the graphene layer is N-type doped.

Please refer to FIG. 6B, which illustrates Raman spectroscopy measurement when various concentrations of the TiOx are utilized as the doping layer. An excitation wavelength is 633 nm. Since the graphene layer is N-type doped, 2D bands of the graphene transistor is shifted down from 2644 cm ⁻¹ (pristine) to 2634 cm⁻¹ (the concentration of 10 mg/mL of the TiOx) and 2632 cm⁻¹ (the concentration of 20 mg/mL of the TiOx), due to the effect of the Fermi level shift on phonon frequencies.

Please refer to FIG. 7, which illustrates gate-dependent conductivity a when various concentrations of the TiOx are utilized as the doping layer. The graphene transistors by utilizing various concentrations of the TiOx are measured at a vacuum condition of 10⁻⁴ torr. With the increased concentrations of the TiOx, the Dirac points are shifted toward negative gate voltages. This represents that the graphene layer is N-type doped.

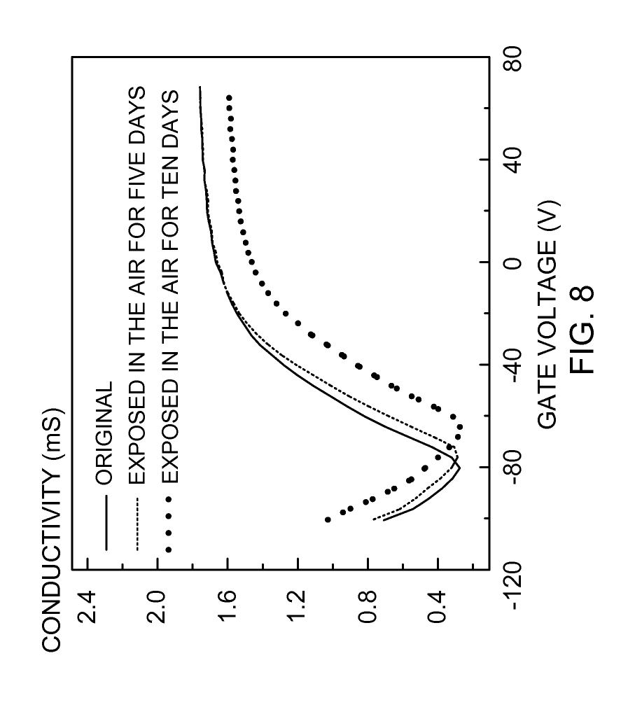

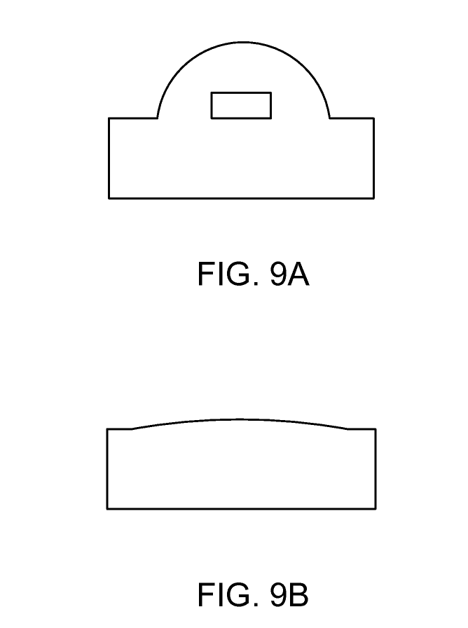

FIG. 8, FIG. 9A and FIG. 9B describe that the graphene transistor of the present invention has a superior air stability.

Please refer to FIG. 8, which illustrates gate-dependent conductivity curves when the graphene transistor in FIG. 3 (comprising two doping layers) is exposed in the air. When the graphene transistor is exposed in the air for five days, the Dirac voltage is shifted from −80 volts to −78 volts. When the graphene transistor is exposed in the air for ten days, the Dirac voltage is −62 volts. Compared with the conventional graphene transistor, the graphene transistor of the present invention by utilizing the TiOx as the doping layer is not easily affected by the environment, that is, the graphene transistor of the present invention has a superior air stability.

Please refer to FIG. 9A and FIG. 9B. FIG. 9A illustrates a contact angle of the doping layer (TiOx) disposed on the insulating layer (SiO₂) as shown in FIG. 1 in the graphene transistor of the present invention. FIG. 9B illustrates a contact angle of the insulating layer (SiO₂) in the conventional graphene transistor. The TiOx/SiO₂ structure of the present invention has the contact angle of 76 degrees. This represents that the TiOx/SiO₂ structure of the present invention is hydrophobic. The insulating layer of the conventional graphene transistor has the contact angle of 7 degrees. This represents that the insulating layer of the conventional graphene transistor is hydrophilic. Accordingly, the TiOx/SiO₂ structure of the present invention can decrease influence of vapor significantly.

The graphene transistor of the present invention has the following advantages. First, by utilizing the nonstoichiometric compounds as the doping layer, the graphene transistor of the present invention has a superior doping effect than that of the conventional graphene transistor. Second, the carrier mobility is not reduced. Third, disposing the doping layer on the graphene layer for sealing the graphene layer is capable of preventing the graphene layer from being affected by the air and vapor in the environment and avoiding that the doping level is reduced. Fourth, the doping layer may be formed by the simple solution process and is not required to be formed by the high temperature process.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A graphene transistor, comprising:
a source electrode;
a drain electrode;
a graphene layer disposed between the source electrode and the drain electrode;
an insulating layer;
a gate electrode separated from the graphene layer, the source electrode and the drain electrode by the insulating layer; and
at least one doping layer disposed on the graphene layer or beneath the graphene layer for providing dopants for the graphene layer, and the doping layer comprising nonstoichiometric compounds.

2. The graphene transistor of claim 1, wherein the nonstoichiometric compounds comprise TiOx.

3. The graphene transistor of claim 2, wherein the doping layer is formed by a TiOx film.

4. The graphene transistor of claim 1, wherein the doping layer is disposed on the graphene layer and covers the whole graphene layer.

5. The graphene transistor of claim 1, wherein the doping layer is disposed on the graphene layer and only covers a part of the graphene layer.

6. The graphene transistor of claim 1, wherein the doping layer has a thickness of from about 10 nm to about 50 nm.

7. The graphene transistor of claim 1, comprising two doping layers respectively disposed on the graphene layer and beneath the graphene layer, wherein the doping layer disposed on the graphene layer covers the whole graphene layer.

8. The graphene transistor of claim 1, comprising two doping layers respectively disposed on the graphene layer and beneath the graphene layer, wherein the doping layer disposed on the graphene layer only covers a part of the graphene layer.

9. The graphene transistor of claim 1, which is a bottom-gate transistor.

10. The graphene transistor of claim 1, which is a top-gate transistor.

11. A graphene transistor, comprising:
a source electrode;
a drain electrode;
a graphene layer disposed between the source electrode and the drain electrode;
an insulating layer;
a gate electrode separated from the graphene layer, the source electrode and the drain electrode by the insulating layer; and
a doping layer disposed on the graphene layer for sealing the graphene transistor, and the doping layer comprising nonstoichiometric compounds.

12. The graphene transistor of claim 11, wherein the nonstoichiometric compounds comprise TiOx.

13. The graphene transistor of claim 12, where the doping layer is formed by a TiOx film.

14. The graphene transistor of claim 11, wherein the doping layer has a thickness of from about 10 nm to about 50 nm.

15. The graphene transistor of claim 11, which is a bottom-gate transistor.

16. The graphene transistor of claim 11, which is a top-gate transistor.
